(19) United States
(12) Patent Application Publication
(10) Pub. No.: US 2022/0214161 A1
(43) Pub. Date: Jul. 7, 2022

(54) METHOD FOR NON-DESTRUCTIVE INSPECTION OF A STRUCTURE AND CORRESPONDING SYSTEM

(71) Applicant: SCHOTT AG, Mainz (DE)

(72) Inventors: Stephan CORVERS, Oestrich-Winkel (DE); Christoph LOHO, Darmstadt (DE); Thomas KORB, Partenheim (DE)

(73) Assignee: SCHOTT AG, Mainz (DE)

(21) Appl. No.: 17/568,752

(22) Filed: Jan. 5, 2022

(30) Foreign Application Priority Data
Jan. 5, 2021 (EP) 21 150 331.3

(51) Int. Cl. G01B 11/24; H01L 21/48; G01B 11/30; B08B 3/08

(52) U.S. Cl. CPC G01B 11/2441; B08B 3/08; G01B 11/30; H01L 21/486

(57) ABSTRACT

The present disclosure relates to a method for non-destructive inspection of a structure, preferably a through-glass via, TGV, of a substrate, preferably a glass substrate, comprising the steps of:
applying a moldable mass onto a surface of the structure of the substrate;
hardening of the moldable mass so that the mass is elastic;
non-destructive removing of the elastic mass from the structure; and
analyzing the removed elastic mass according to at least one parameter, preferably a quality parameter.

### CROSS-REFERENCE TO RELATED APPLICATION

The present application claims the benefit under 35 U.S.C. § 119 of European Patent Application No. EP 21 150 331.3, filed on Jan. 5, 2021, which is herein incorporated by reference.

### BACKGROUND OF THE DISCLOSURE

### 1. Field of the Disclosure

The present disclosure relates to a method, system and substrate for non-destructive inspection of a structure, preferably a through-glass via (TGV) of a substrate, preferably a glass substrate.

### 2. Discussion of the Related Art

In the semiconductor industry, through-glass vias (TGV) help to further miniaturize semiconductor devices. The ability to evaluate the quality of TGVs in substrates for the semiconductor industry is important for high volume manufacturing of structured glass for the semiconductor industry. To ensure quality of TGVs, some of the manufactured glass substrates have been examined using destructive testing. The glass substrate is cut to obtain a cross-section, in which the surface roughness is evaluated through optical or electron microscopy.

Another conventional method is to perform complex optical measurements of the TGVs that require mechanical displacement of the substrate. Each individual TGV is analyzed two dimensionally from the top and bottom opening of the via, and an indirect measurement of the perpendicularity is obtained. This measurement does not allow for determination of the properties of the inner surface of the TGV, such as roughness, which is important to optimal metallization and signal propagation.

Embodiments of the present disclosure therefore address the problem of providing a method for inspecting a structure on or in a substrate, which is easy to implement, provides a high accuracy when determining quality parameters of the structure and enables non-destructive inspection of a structure.

### SUMMARY OF THE DISCLOSURE

The present disclosure relates to a method for non-destructive inspection of a structure, preferably a through-glass via (TGV) of a substrate, preferably a glass substrate.

The present disclosure further relates to a system for non-destructive inspection of a structure, preferably a through-glass via (TGV) of a substrate, preferably a glass substrate.

The present disclosure even further relates to a method for manufacturing a structure preferably a through-glass via (TGV) of a substrate, preferably a glass substrate.

Although applicable to any kind of substrate, the present disclosure will be described in the context of a substrate in form of a glass substrate.

Although applicable to any kind of structure, the present disclosure will be described in the context of a structure in form of a through glass via (TGV).

In an embodiment, the present disclosure provides a method for non-destructive inspection of a structure, preferably a through-glass via, TGV, of a substrate, preferably a glass substrate, comprising the steps of:

applying a moldable mass onto a surface of the structure of the substrate,

hardening of the moldable mass such that the mass is elastic,

non-destructive removing of the elastic mass from the structure, and

analyzing the removed elastic mass according to at least one parameter, preferably a quality parameter.

In a further embodiment, the present disclosure provides a system for non-destructive inspection of a structure, preferably a through-glass via, TGV, of a substrate, preferably a glass substrate, comprising:

an applying entity adapted for applying a moldable mass onto a surface of the structure of the substrate,

a hardening entity adapted for hardening of the moldable mass, such that the mass is elastic,

a removing entity adapted for non-destructive removing of the elastic mass from the structure, and

an analyzing entity adapted for analyzing the removed elastic mass according to at least one parameter, preferably a quality parameter.

In a further embodiment, the present disclosure provides a method for manufacturing a structure preferably a through-glass via, TGV, of a substrate, preferably a glass substrate, comprising the steps of:

providing a substrate,

forming a structure in and/or on the substrate, and

inspecting the structure by performing the method described above.

In an even further embodiment, the present disclosure provides a substrate, preferably a glass substrate, comprising a structure, preferably a through-glass via, TGV, provided by a method according to the method of the immediately preceding paragraph.

In sum, the present disclosure provides inter alia a non-destructive method and a corresponding system using a moldable mass hardened to an elastic mass as a proxy for the structured substrate, preferably comprising glass. The moldable mass hardened, later to an elastic mass, is shaped with great accuracy in or on the structures of the substrate and removed without damaging a costly structured substrate. The elastic mass' surface is then examined to determine one or more selected key performance indicators, such as surface roughness, geometry of the structure (preferably a via), circularity, diameter throughout the via, depression depth, taper angle, waist size, perpendicularity, deviation from cylindrical geometry, and the like. In addition, although the elastic mass can also leave a residue that is undesirable for further processing of the structure, e.g. metallization, it can be easily removed through cleaning processes, e.g. known in the semiconductor industry.

The term “non-destructive removing” with regard to the term “elastic mass” is to be understood in its broadest sense and refers preferably in the description, in particular in the claims, to a method, which enables relocating, removing, detaching, disconnecting, dislodging or the like of the elastic mass from the structure, so that neither the structure nor the elastic mass is damaged, modified or amended. The structure is in particular not damaged, modified or amended in such a way that further processing of the structure is not affected. In particular, that means that the relevant properties, features, quality or characteristics of the structure, the substrate and the elastic mass are not amended, changed or modified due to relocating, removing, detaching, disconnecting or dislodging.

For instance, conventional quality assurance measurements for TGVs in a glass substrate, such as surface roughness and geometry, require a cross-section to be cut through the glass article, thereby destroying it and reducing overall product yield. A non-destructive method according to embodiments of the present disclosure using an elastic mass improves yield thereby avoiding this deficiency. Furthermore, a cut-out cross-section enables only a limited number of structures to be evaluated, whereas the elastic mass according to embodiments of the present disclosure allows a significantly larger number of structures to be evaluated. Another disadvantage of cross-section measurements is that the TGV is not perfectly cut across, limiting the ability to evaluate the geometry.

One of the advantages, which can be accomplished by embodiments of the present disclosure is an easy implementation. One of the further advantages, which can be accomplished by embodiments of the present disclosure, is a non-destructive measurement of properties or characteristics of structures in and/or on a substrate. One of the advantages, which can be accomplished by embodiments of the present disclosure, is a flexibility in terms of quality parameters describing the properties of the structure of the substrate.

One of the further advantages, which can be accomplished by embodiments of the present disclosure, is that microstructures, for instance through glass vias having a diameter of less than 500 micrometers, preferably less than 250 micrometers, preferably 100 micrometers or even lower up to 5 micrometers, can be easily, reliably and non-destructively inspected.

Further features, advantages and further embodiments are disclosed or can become apparent in the following.

According to an embodiment of the disclosure the hardening is performed by applying at least one of:

chemical hardening, preferably by adding additional chemical additives,

electromagnetic radiation, preferably IR-radiation and/or UV-radiation,

solidification and/or conglomeration from a solution by volatilization of a solvent, and

cooling and/or heating.

One of the advantages can be that flexibility is enhanced since a variety of different hardening methods can be used depending on the moldable mass composition. For instance, multi-component-systems can be used, which can provide a polyaddition reaction and/or a condensation reaction hardening the multi-component systems. Further, chemical hardening can include a polymerization of one or more monomers to a polymer by at least one of:

step-growth polymerization, where pairs of reactants combine in steps to the polymer, for instance polysiloxane, polyether, polyurethane or the like,

chain-growth polymerization, where monomers are added to a growing chain with an active center forming the polymer. The active center needs to be formed once, for instance ethylene polymerizes by adding a catalyst—a common catalyst is titanium (III) chloride as an example for a so-called Ziegler-Natta catalyst.

photopolymerization, where most of these types of reactions are chain-growth polymerization methods being initiated by absorption of visible or UV light.

Chemical hardening includes but is not limited to curing. Curing is a chemical process that produces the toughening or hardening of a polymer material by chain-growing and/or cross-linking, initiated by heat, radiation, electron beams and/or chemical additives. The chemical additives include also environmental substances like water provided as air humidity or the like. For instance, materials of a variety of different properties such as hardness, elasticity, durability can be obtained by heating of natural rubber with sulfur. Other methods provide polymerization to obtain thermoplastics or elastomers. Polymers in the form of thermoplastics can be obtained from a drying solution. Thermoplastic elastomers can be obtained by liquefaction by applying heat.

According to an embodiment of the present disclosure, the hardening is performed within less than 1 hour, preferably less than 15 minutes, preferably less than 10 minutes, preferably less than 5 minutes. One of the advantages can be that a fast and efficient inspecting method can be achieved.

According to an embodiment of the present disclosure the elastic mass has a shore hardness below 70 A, preferably between 25 A and 65 A, preferably between 50 A and 60 A, after removal of the elastic mass from the surface. For instance, the shore hardness can vary over time, in particular increasing within 24 hours after removal up to 20%. Shore hardness of a removed elastic mass after 10 minutes can be 47 A, after one hour 48 A and after 24 hours 51 A. The values of the shore hardness specified here can all allow realizing a detailed inspection and a non-destructive removal of the elastic mass. In another example, a quick hardening can be obtained for a moldable mass with an application time of about 1.5 to 2 minutes and a hardening time of about 2 to 3 minutes. Preferably, the shore hardness is then determined at least within a time window of 5 to 15 minutes after removing the elastic mass from the structure. This can provide the advantage of a detailed inspection and a non-destructive removal of the elastic mass. Parameters include but are not limited to shore hardness, tensile strength, yield strength, elastic modulus, and elasticity. The parameters can be obtained for example based on DIN 65378, ISO 527-1 and/or according to Microtensile ASTM D1708 in the respective current version valid as of Dec. 1, 2020.

According to an embodiment of the present disclosure, the structure of the substrate is provided in form of at least one of a groove, a cavity, a trench, a channel, an indentation, preferably in form of a scratch, a via, a blind hole, an edge, a rim, a pillar. This can provide the advantage of an enhanced flexibility of inspecting a large variety of different shaped structures.

According to an embodiment of the present disclosure, the elastic mass is provided having a mold precision below 1 micrometer, preferably below 0.5 micrometer, preferably below 0.1 micrometer. This can provide the advantage of inspecting small structures and their surfaces in particular of structures used in semiconductor industry.

According to an embodiment of the present disclosure, the moldable mass is provided in form of at least one of a thermoplastic, an elastomer, preferably silicone, rubber, resin and/or epoxy, an adhesive. This can provide the advantage of an easy adaption to the form or shape of the surface of the structure as well as of the material of the substrate enabling a precise inspection.

According to an embodiment of the present disclosure, the at least one parameter represents a surface roughness of the structure and/or a geometry of the structure. This can provide the advantage of providing relevant information about the structure for further processing.

According to an embodiment of the present disclosure, the parameter representing geometry specifies at least one of surface area, volume, height, length, width, circularity, diameter, depression depth, taper angle, hour glass angle, waist size, perpendicularity, and/or deviation from a theoretical structure. This can provide the advantage of providing detailed information about the structure for further processing.

According to an embodiment of the present disclosure, the parameter representing geometry is determined using light microscopy and/or the parameter representing surface roughness is determined using light interference spectroscopy. This can provide the advantage of an easy and reliable determination of the relevant parameters.

According to an embodiment of the present disclosure, the at least one parameter is determined using light microscopy and/or interference spectroscopy, computer tomography, electron microscopy and/or fluorescence spectroscopy. This can provide the advantage of an easy and reliable determination of the relevant parameters.

According to an embodiment of the system, the analyzing entity comprises at least one of a microscopy entity, preferably a light microscopy entity and/or an electron microscopy entity, a spectrometer entity, preferably an interference and/or fluorescence spectrometer entity, a tomography entity, preferably a computer tomography entity and/or a magnetic resonance imaging entity. This can provide the advantage of a precise and reliable determination of parameters in particular based on the surface structure or texture of the removed elastic mass.

According to an embodiment of the system, the system further comprises at least one of:

a holding entity adapted for holding a substrate, the substrate comprising at least one structure,

a feeder entity adapted to feed the substrate to at least one other entity,

a supplying entity adapted to supply the moldable mass to the applying entity,

a display entity adapted to display at least one of

a 2D and/or 3D image of the elastic mass,

a result of the analysis, or

a 2D and/or 3D image of the structure.

This can provide the advantage of an easy handling and processing for inspection of the structure.

According to an embodiment of the method for manufacturing prior to inspecting the structure and/or after removing of the elastic mass from the structure, the surface of the structure is cleaned by applying one or more cleaning procedures, preferably comprising at least one of one or more intense alkaline cleaners, one or more acidic cleaners, one or more neutral cleaners, one or more rinsing fluids, preferably carried out in one or more tempered ultrasonic and/or megasonic baths. Multiple cleaning procedures can be applied subsequently using different baths and using different times within the baths, between the baths a rinsing can be applied—interim rinsing. This can provide the advantage of ease of further processing by avoiding processing errors due to potential pollution by remnants of the elastic mass. The term “ultrasonic” refers here to frequencies reaching from 20 kHz to 400 kHz. The term “megasonic” refers here to frequencies reaching from 400 kHz to 2 MHz. In particular, megasonic cleaning can be used to remove particles having size below the micrometer regime.

According to an embodiment of the method for manufacturing prior to performing a cleaning procedure, the surface to be cleaned is measured in order to obtain a pollution indication parameter of the surface, and when the pollution indication parameter exceeds a threshold, the cleaning procedure is performed. This can provide the advantage of more efficient manufacturing, since for instance cleaning procedures are only performed when a certain level of pollution of the structure is determined.

There are several ways to design and further develop the teachings of the present disclosure in an advantageous way. In connection with the explanation of the preferred embodiments of the disclosure by the aid of the drawing, generally preferred embodiments and further developments of the teaching will be explained.

### BRIEF DESCRIPTION OF THE DRAWINGS

FIG. 1 shows a microscope image of a microsection of a TGV of a substrate according to an embodiment of the present disclosure.

FIG. 2 shows a microscope image of an elastic mass removed from a TGV of the substrate of FIG. 1.

FIG. 3 shows a microscope image of a microsection of a TGV of a substrate according to an embodiment of the present disclosure.

FIG. 4 shows a microscope image of an elastic mass removed from a TGV of the substrate of FIG. 3.

FIG. 5 shows steps of a method for non-destructive inspection of a structure, of a substrate according to an embodiment of the present disclosure.

FIG. 6 shows schematically a system for non-destructive inspection of a structure, of a substrate according to an embodiment of the present disclosure.

FIG. 7 shows steps of a method for manufacturing of a structure of a substrate according to an embodiment of the present disclosure.

### DETAILED DESCRIPTION OF THE DISCLOSURE

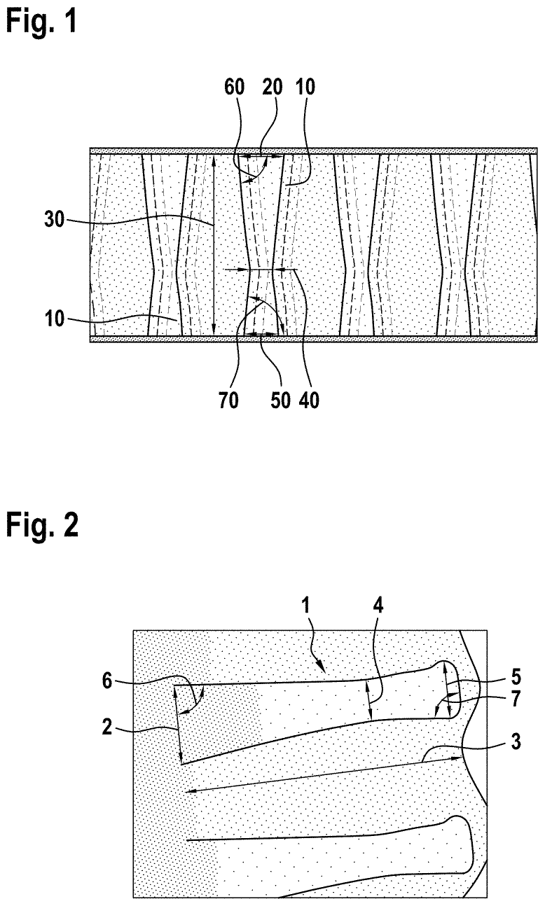

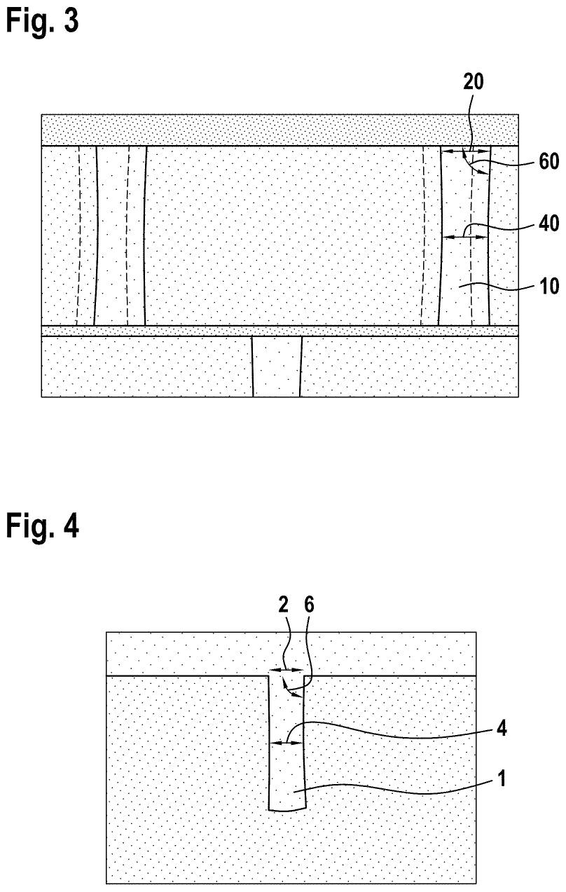

FIG. 1 shows a microscope image of a microsection of a TGV of a substrate according to an embodiment of the present disclosure. FIG. 2 shows a microscope image of an elastic mass removed from a TGV of the substrate of FIG. 1. FIG. 1 and also FIG. 3 show a plurality of same TGVs in the plane of projection and also behind one another perpendicular to the plane of projection, the latter shown in dashed lines.

In detail, FIG. 1 shows a microscopic image comprising a plurality of generally identical through-glass vias TGV 10, i.e. manufactured with the same manufacturing method. The TGV 10 is measured having the following properties:
taper angle 60 at the top of about 85 degrees,
taper angle 70 at the bottom of about 84.5 degrees,
top diameter 20 of about 145 micrometers,
bottom diameter 50 of about 111 micrometers,
neck diameter 40 of about 76 micrometers, and
length 30 of about 560 micrometers.

FIG. 2 shows an elastic mass 1 in form of silicone, filled into the TGV 10, hardened and then removed from the TGV 10. The elastic mass 1 is measured having the following properties:
taper angle 6 at the top of about 87 degrees,
taper angle 7 at the bottom of about 86 degrees,
top diameter 2 of about 151 micrometers,
bottom diameter 5 of about 110 micrometers,
neck diameter 4 of about 79 micrometers, and
length 3 of about 542 micrometers.

As can be observed through comparison of the measured properties of the TGV 10 and its “negative image” in form of the elastic mass 1, the properties are in good agreement with each other.

FIG. 3 shows a microscope image of a microsection of a TGV of a substrate according to an embodiment of the present disclosure. FIG. 4 shows a microscope image of an elastic mass removed from a TGV of the substrate of FIG. 3.

In detail, FIG. 3 shows a microscopic image comprising a plurality of the same through-glass via TGV 10. The TGV 10 is measured having the following properties:
taper angle 60 at the top of about 89 degree,
top diameter 20 of about 149 micrometers, and
neck diameter 40 of about 138 micrometers.

These values have been obtained by measuring 10 TGV L1-L10:

| Microsection | Diameter Top | Taper Angle | Diameter neck |
|---|---|---|---|
| VIA # | [μm] | Top [°] | [μm] |
| L1 | 148.5 | 89.3 | 137.8 |
| L2 | 150.1 | 88.9 | 138.2 |
| L3 | 151.2 | 89.3 | 139.9 |
| L4 | 150.1 | 88.7 | 139.4 |
| L5 | 147.4 | 89.1 | 138.3 |
| L6 | 149.6 | 88.7 | 139.4 |
| L7 | 149.1 | 88.9 | 135.6 |
| L8 | 148.5 | 88.8 | 134.6 |
| L9 | 147.5 | 89.5 | 138.9 |
| L10 | 150.7 | 88.8 | 140.5 |
| MEAN | 149 | 89 | 138 |
| StDev. | 1 | 0 | 2 |

FIG. 4 shows an elastic mass 1 in form of silicone, filled into the TGV 10, hardened and then removed from the TGV 10. The elastic mass 1 is measured having the following properties:
taper angle 60 at the top of about 89 degree,
top diameter 20 of about 149 micrometers, and
neck diameter 40 of about 141 micrometers.

These values have been obtained by measuring 18 elastic masses in the form of silicone.

| Silicone | Diameter Top | Taper Angle | Diameter neck |
|---|---|---|---|
| stamp # | [μm] | Top [°] | [μm] |
| S1 | 152 | 89.6 | 144 |
| S2 | 150 | 89.6 | 141 |
| S3 | 151 | 89.6 | 140 |
| S4 | 149 | 89.1 | 139 |
| S5 | 144 | 89.5 | 137 |
| S6 | 148 | 88.9 | 138 |
| S7 | 148 | 88.8 | 138 |
| S8 | 143 | 88.7 | 136 |
| S9 | 148 | 88.9 | 138 |
| S10 | 148 | 88.6 | 137 |
| S11 | 148 | 88.6 | 143 |
| S12 | 148 | 88.1 | 142 |
| S13 | 148 | 88.3 | 145 |
| S14 | 152 | 87.8 | 142 |
| S15 | 147 | 88.6 | 139 |
| S16 | 152 | 88 | 148 |
| S17 | 151 | 88.1 | 142 |
| S18 | 152 | 88.5 | 140 |
| MEAN | 149 | 89 | 141 |
| StDev. | 3 | 1 | 3 |

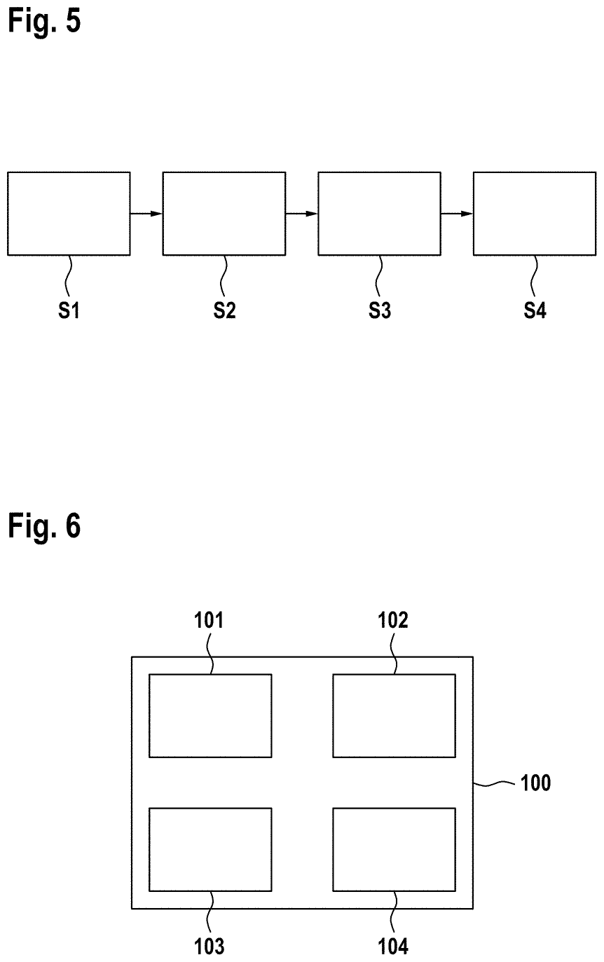

FIG. 5 shows steps of a method for non-destructive inspection of a structure, of a substrate according to an embodiment of the present disclosure.

In detail, FIG. 5 shows steps of a method for non-destructive inspection of a structure, preferably a through-glass via, TGV, of a substrate, preferably a glass substrate.

The method comprises the steps of:
applying (S1) a moldable mass onto a surface of the structure of the substrate,
hardening (S2) of the moldable mass such that the mass is elastic,
non-destructive removing (S3) of the elastic mass from the structure, and
analyzing (S4) the removed elastic mass according to at least one parameter, preferably a quality parameter.

FIG. 6 schematically shows a system for non-destructive inspection of a structure, of a substrate according to an embodiment of the present disclosure.

In detail, FIG. 6 schematically shows a system for non-destructive inspection of a structure, preferably a through-glass via, TGV, of a substrate, preferably a glass substrate. The system 100 comprises an applying entity 101 adapted for:
applying a moldable mass onto a surface of the structure of the substrate,
a hardening entity 102 adapted for hardening of the moldable mass, such that the mass is elastic,
a removing entity 103 adapted for non-destructive removing of the elastic mass from the structure, and
an analyzing entity 104 adapted for analyzing the removed elastic mass according to at least one parameter, preferably a quality parameter.

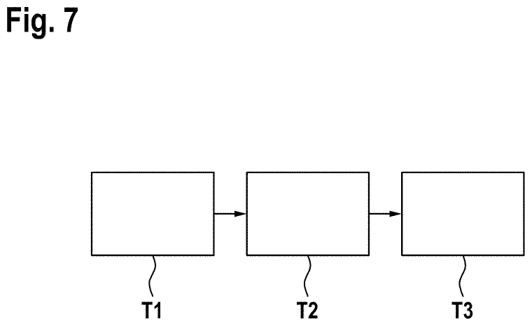

FIG. 7 shows steps of a method for manufacturing of a structure of a substrate according to an embodiment of the present disclosure.

In detail, FIG. 7 shows steps of a method for manufacturing a structure preferably a through-glass via, TGV, of a substrate, preferably a glass substrate.

The method comprises the steps of:
providing T1 a substrate,
forming T2 a structure in and/or on the substrate, and
inspecting T3 the structure by performing a previously-described method.

In summary, the present disclosure can provide and/or enable the following features and/or advantages:
easy implementation,
precise measurement of properties of structures of substrates,
cost-effective manufacturing and further processing of substrates with structures,
easy handling and processing,
high flexibility in terms of quality parameters,
high flexibility in terms of measuring methods for quality parameters, and
non-destructive inspection of structures in and/or on substrates.

Many modifications and other embodiments of the disclosure set forth herein will come to mind to the one skilled in the art to which the disclosure pertains, having the benefit of the teachings presented in the foregoing description and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation.

### LIST OF REFERENCE SIGNS

1 Elastic mass
2 Top diameter
3 Length
4 Neck diameter
5 Bottom diameter
6 Taper angle
7 Taper angle
10 TGV
20 Top diameter
30 Length
40 Neck diameter
50 Bottom diameter
60 Taper angle
70 Taper angle
100 System
101 Applying entity
102 Hardening entity
103 Removing entity
104 Analyzing entity
S1-S4 Steps according to the method of the present disclosure
T1-T3 Steps according to the method of the present disclosure

What is claimed is:

1. A method for non-destructive inspection of a through-glass via, TGV, of a substrate comprising the steps of:
applying a moldable mass onto a surface of a structure of the substrate;
hardening the moldable mass so that the mass is elastic;
removing the elastic mass from the structure in a non-destructive manner; and
analyzing the removed elastic mass according to at least one parameter.

2. The method according to claim 1, wherein the parameter is a quality parameter.

3. The method according to claim 1, wherein the hardening step is performed by applying at least one of:
chemical hardening;
electromagnetic radiation;
solidification and/or conglomeration from a solution by volatilization of a solvent;
cooling; and
heating.

4. The method according to claim 1, wherein the hardening is performed within less than 5 minutes.

5. The method according to claim 1, wherein the elastic mass has a shore hardness below 70 A after removal of the elastic mass from the surface.

6. The method according to claim 1, wherein the elastic mass has a shore hardness between 50 A and 60 A after removal of the elastic mass from the surface.

7. The method according to claim 1, wherein the structure of the substrate is at least one of a groove, a cavity, a trench, a channel, an indentation, a via, a blind hole, an edge, a rim or a pillar.

8. The method according to claim 1, wherein the elastic mass has a mold precision below 1 micrometer.

9. The method according to claim 1, wherein the moldable mass is at least one of a thermoplastic, an elastomer, a rubber, a resin, an epoxy, and an adhesive.

10. The method according to claim 1, wherein the at least one parameter represents a surface roughness of the structure and/or a geometry of the structure.

11. The method according to claim 1, wherein the at least one parameter represents a geometry of the structure, and specifies at least one of surface area, volume, height, length, width, circularity, diameter, depression depth, taper angle, hour glass angle, waist size, perpendicularity and deviation from a theoretical structure.

12. The method according to claim 11, wherein the parameter representing geometry is determined using light microscopy, and/or wherein the parameter representing surface roughness is determined using light interference spectroscopy.

13. The method according to claim 1, wherein the at least one parameter is determined using light microscopy, interference spectroscopy, computer tomography, electron microscopy, and fluorescence spectroscopy.

14. A system for non-destructive inspection of a structure of a substrate, comprising:
an applying entity adapted for applying a moldable mass onto a surface of the structure of the substrate;
a hardening entity adapted for hardening of the moldable mass, so that the mass is elastic;
a removing entity adapted for non-destructive removing of the elastic mass from the structure; and
an analyzing entity adapted for analyzing the removed elastic mass according to at least one parameter.

15. The system of claim 14, wherein the analyzing entity comprises at least one of a microscopy entity, a spectrometer entity, a tomography entity, and a magnetic resonance imaging entity.

16. The system of claim 14, wherein the substrate is a glass substrate.

17. The system according to claim 14, wherein the system further comprises at least one of:
a holding entity adapted for holding a substrate, the substrate comprising at least one structure;
a feeder entity adapted to feed the substrate to at least one other entity;
a supplying entity adapted to supply the moldable mass to the applying entity; and
a display entity adapted to display at least one of a 2D and/or 3D image of the elastic mass, a result of the analysis, and a 2D and/or 3D image of the structure.

18. A method of manufacturing a structure, comprising the steps of:
providing a substrate;
forming a structure in and/or on the substrate; and
inspecting the structure by performing the method according to claim 1.

19. The method according to claim 18, further comprising the step of, prior to inspecting the structure and/or after removing of the elastic mass from the structure, cleaning the surface of the structure by applying one or more cleaning procedures.

20. The method according to claim 19, wherein the cleaning procedures use at least one of:
one or more intense alkaline cleaners;
one or more acidic cleaners;
one or more neutral cleaners; and
one or more rinsing fluids.

21. The method of claim 20, wherein prior to performing the cleaning step the surface to be cleaned is measured to obtain a pollution indication parameter of the surface and wherein when the pollution indication parameter exceeds a threshold the cleaning procedure is performed.
